(19) United States
(12) Patent Application Publication
(10) Pub. No.: US 2018/0094352 A1
(43) Pub. Date: Apr. 5, 2018

(54) SYSTEMS AND METHODS FOR METAL LAYER ADHESION

(71) Applicant: UChicago Argonne, LLC, Chicago, IL (US)

(72) Inventors: Anil U. Mane, Naperville, IL (US); Jeffrey W. Elam, Elmhurst, IL (US)

(21) Appl. No.: 15/281,824

(22) Filed: Sep. 30, 2016

(51) Int. Cl. C23C 16/455; H01L 21/768; C23C 16/02; C23C 16/06

(52) U.S. Cl. CPC C23C 16/45553; H01L 21/7685; C23C 16/45527; C23C 16/0272; C23C 16/06; H01L 21/76885

(57) ABSTRACT

A method for creating a thin film. A barrier layer is applied to a substrate and a metal layer deposited on the thin film. The barrier layer may comprise a tungsten composition and the metal layer may comprise pure tungsten.

The United States Government claims certain rights in this invention pursuant to Contract No. W-31-109-ENG-38 between the United States Government and the University of Chicago and/or pursuant to DE-AC02-06CH111357 between the United States Government and UChicago Argonne, LLC representing Argonne National Laboratory.

### TECHNICAL FIELD

The present disclosure relates generally to systems and methods for thin layer films. More specifically, for systems and methods to improve metal, such as tungsten, layer adhesion and nucleation which enhance the metal grain growth and hence the increases electrical conductivity.

### BACKGROUND

At present thin films of W are widely used in semiconductor microelectronic logic and memory devices, as integrated device wirings and contact metallization. At the moment typical W layers are grown by atomic layer deposition (ALD) and chemical vapor deposition (CVD) methods on variety of substrates (e.g. silicon, Cu and oxide surfaces). Further, thin films of tungsten are also used for 3D integrated circuit wiring, barrier for copper, and through substrate vias for 3D device packaging e.g. TSV, TGV, etc.).

In semiconductor manufacturing facilities (FABs) the most common and economical precursor for W CVD and ALD processes is WF6, and is used to grow a variety of thin films of W including high and low resistivity W. In a thin film deposition process, WF6 is used in conjunction with a reducing agent such as SiH4, B2H6, H2 or Si2H6. To grow thin films of W uniformly and robustly an intermediate thin film metal barrier such as WNx, TiN, TaN, oxides or their combinations are used. This thin metal barrier (acts as a glue layer) helps the W thin film adhere strongly to the substrate as well as help to reduce W the nucleation time and permit shorter processing times. Strong adhesion of the W layer is necessary so that the W film remains intact during subsequent chemical mechanical polishing (CMP) steps in the semiconductor device process flow.

At the same time, as device dimensions shrink, as the thickness and electrical resistance of this W-based wiring layer become increasingly important, especially in high aspect ratio narrow trenches, the thickness of the W related layer need to reduce, This effects overall total line resistance of the W and barrier. Further barrier thickness is also needs to reduce greatly otherwise the total line resistance becomes unacceptably high. At the same time if barrier layer thickness is reduced, then adhesion of W is greatly affected. In addition deposition of these barrier adhesion layers can sometimes require additional precursors (e.g. TiN (TDMAT and NH3) as well as additional deposition equipment and processing steps such as wafer transfer, heating and cooling, and this can severely increase cost of ownership and decrease throughput. Further for next generation devices critical dimension of the device features there will be physical thickness limit for the metal barrier as well as pure W that need to grow uniformly over high aspect ratio 3D multi-stack architectures.

### SUMMARY

Embodiments described herein relate generally to a method of preparing a tungsten layer on a substrate. The method comprises: depositing a barrier layer on the substrate by 1) performing atomic layer deposition of WF₆ at a first deposition temperature between 100° C. and 400° C., 2) purging the WF₆; 3) performing atomic layer deposition of TMA at a second deposition temperature between 100° C. and 400° C., and 4) purging the TMA. Further, the method includes depositing a tungsten layer on the barrier layer by: 1) performing atomic layer deposition of WF₆ at a third deposition temperature between 100° C. and 400° C.; 2) purging the WF₆; 3) performing atomic layer deposition of a reducing precursor at a fourth deposition temperature between 100° C. and 400° C.; and 4) purging the reducing precursor.

Some embodiments relate to a method of preparing a tungsten layer on a substrate. The method comprises depositing a barrier layer comprising M₁C_{z}/M₂Xₘ on the substrate by performing a cycles of ALD comprising: 1) deposition of a metal precursor M₁Xₙ(g) at a first deposition temperature between 100° C. and 400° C.; 2) purging the metal precursor; 3) deposition of a coreactant precursor M₂Rₘ(g) at a second deposition temperature between 100° C. and 400° C.; and 4) purging the coreactant precursor. M₁ is a first metal, wherein M₂ is a second metal X is a halogen, R is an alkyl ligand. The method further comprises depositing a tungsten layer on the barrier layer by performing b cycles of ALD comprising: 1) deposition of a second metal precursor at a third deposition temperature between 100° C. and 400° C. and deposition of a reducing precursor at a fourth deposition temperature between 100° C. and 400° C.

Some embodiments relate to an article of manufacture. The article comprises a substrate, a barrier layer, and a tungsten layer. The barrier layer comprising AlWₓF_{y}C_{z}, where x and y are any non-zero positive number and wherein z is be zero or any positive number. The tungsten layer deposited on the barrier layer.

It should be appreciated that all combinations of the foregoing concepts and additional concepts discussed in greater detail below (provided such concepts are not mutually inconsistent) are contemplated as being part of the subject matter disclosed herein. In particular, all combinations of claimed subject matter appearing at the end of this disclosure are contemplated as being part of the subject matter disclosed herein.

### BRIEF DESCRIPTION OF DRAWINGS

The foregoing and other features of the present disclosure will become more fully apparent from the following description and appended claims, taken in conjunction with the accompanying drawings. Understanding that these drawings depict only several implementations in accordance with the disclosure and are therefore, not to be considered limiting of its scope, the disclosure will be described with additional specificity and detail through use of the accompanying drawings.

FIG. 1 illustrates a simplified article of manufacturing with a substrate, barrier layer, and tungsten layer.

FIG. 2 is a photograph of W deposited on a pure silicon substrate (right half of the 300 mm wafer shows worse delamination) and on ALD grown Al2O3(20 nm)/Si(100) wafer (left half of the 300 mm wafer, shows no delamination)

FIG. 3A is a photograph of an adhesion test on a W coated substrate comprising an 100 nm aluminum oxide barrier layer and a ˜50 nm pure tungsten layer; FIG. 3B shows portions of the tungsten film that have been removed from this wafer using a scotch tape peel test. For this peel test a diamond scriber was used to starch the deposited layer/wafer with reasonable pressure by randomly drawing 3-4 vertical lines and 3-4 horizontal lines. This makes grid-like starches on substrate. Then scotch tape was pressed again the grid like structure and pulled out quickly. This method is used for all the figures.

FIG. 4A is a photograph of an adhesion test on a coated substrate comprising a thin ˜7 nm TW composite barrier layer and a ˜50 nm pure tungsten layer and FIG. 4B shows the results of a scotch tape peel test.

FIG. 5A is a photograph of an adhesion test on a coated substrate comprising a mixture of thin TW barrier layer and a thin tungsten layer with intermediate intervening TW layers and FIG. 5B shows results of a scotch tape peel test.

FIG. 6 is a graph of deposited thin film resistance data as a function of distance on a 300 mm silicon wafer.

FIGS. 7A and 7B illustrate review of a formation of a TW layer by ALD. FIG. 7A illustrates step-wise linear growth. FIG. 7B illustrates saturation for the ALD of FIG. 7A.

FIG. 8A illustrates W nucleation on a on Al2O3 barrier layer. FIG. 8B illustrates W nucleation on a TW barrier layer.

FIGS. 9A and 9B illustrate a W layer on a copper substrate by ALD. FIG. 7a shows bare copper substrate (left image) W layer only on copper substrate (middle image) and W layer with TW barrier on copper substrate. FIG. 9B illustrates the area under the silicon witness coupons shows uniform deposition of W with TW barrier under the area of the solid silicon substrates

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION OF VARIOUS EMBODIMENTS

Embodiments described herein relate generally to thin film technology. Some embodiments specifically relate to Atomic Layer Deposition (ALD). ALD utilizes alternating exposures between precursors (e.g. in a gaseous form) and a solid surface to deposit materials in a monolayer-by-monolayer fashion. One or more precursors bind with the surface and one or more precursors react with prior deposited precursors. The precursors may be applied by micropulse or traditional ALD exposure. A purge may be accomplished by the use of a vacuum or a purge gasafter precursor exposure/deposition. ALD may be arranged in cycles or subcycles having repeating patterns where the number of repeats controls the content and thickness of the deposited layers. U.S. Pat. No. 8,921,799 and pending application published as U.S. Pat. App. Pub. No. 2012/0187305 describe a general method and materials from the method relating to atomic layer deposition of a composite coating.

Some embodiments relate to a method to improve the tungsten (W) thin layer adhesion on various substrates such as, but not limited to, oxides, nitrides, semiconductors, metals and polymers. These substrates can be macroscopic in size, such as a silicon wafer of mm thickness, or the substrate can be a microscopic layer, including a monolayer or more than one layer, such as a thin film of nm thickness. Thus, in one embodiment, a substrate layer 110 may be provided. An article of manufacture may be accomplished by having the substrate layer with a barrier layer 120 disposed thereon and a tungsten layer 130 disposed on the barrier layer 120. Intervening layers of barrier layer 120 may be disposed within the tungsten layer 130 or, alternatively, the article of manufacture may comprise multiple barrier layers and multiple tungsten layers.

In some methods, ALD is used to deposit a barrier layer 120 upon the substrate layer 110. The barrier layer may be a conducting layer. Further, the barrier layer may be an ultrathin layer (such as less than 10 nm, 8 nm, 5 nm, 4 nm, 3 nm, 2 nm, 1 nm, 1 layer, 1 atomic thickness) of barrier layer materials are selected to adhere well to the desired substrates including semiconducting, metal, polymeric substrates. The layers may be a single layer, multiple layers, or submono layer. In one embodiment, the barrier layer comprises a metal composite and is deposited by ALD using a first metal precursor (or barrier layer metal precursor) and a co-reactant precursor reactive with the metal precursor.

In general, the ALD of the metal composite film barrier layer can be expressed as:

M₁Xₙ(g)+M₂Rₘ(g)→M₁C_{z}/M₂Xₘ+products (g)

where M₁Xₙ is the metal precursor and X is a halogen atom (F, Cl, Br, I), M₂Rₘ is the coreactant precursor and R is an alkyl ligand (e.g. —CH3, —C2H3, -Cp where Cp is cyclopentadiene or any of various substituted cyclopentadienes, and -amd where amd is any of various amidinate ligands), M₁C_{z}/M₂Xₘ is the metal composite film, C is carbon, and products (g) represents the volatile reaction products Necessary requirements for this process include that both M₁Xₙ and M₂Rₘ must be volatile compounds, and M₂Xₘ must be non-volatile.

Metal precursors can be WF6, WCl6, WBr5, MoF6, MoF4, MoCl6, TaF5, TaCl5, NbF5, NbCl5, NbBr5, TiF4, TiCl4, TiBr4, TiI4, ZrCl4, HfCl4. Co-reactant precursors can be AlMe3, ZnMe2, ZnEt2, CdMe2, CdEt2, AlEt3, GaMe3, GaEt3, InMe3, InEt3, SnMe4, Mg(Cp)2, Ca(Cp)2, Sr(Cp)2, Ba(Cp)2, Sc(Cp)3, Y(Cp)3, La(Cp)3, where Cp is cyclopentadiene or any of various substituted cyclopentadienes, Co(amd)2, Ni(amd)2, Fe(amd)2, Mg(amd)2, Ca(amd)2, Sr(amd)2, Ba(amd)2, where amd is any of various amidinate ligands.

In one embodiment, the metal precursor comprises a tungsten precursor, for example certain embodiments utilize tungsten hexafluoride (WF₆) and the co-reactant precursor comprises trimethyaluminum (TMA). In such an embodiment, the barrier layer comprises a very stable (WAlFₓC_{y}) composite layer. In yet other embodiments the tungsten precursor is WCl₅ or W(CO)₅ with the co-reactant precursor comprising TMA. In such embodiments, the barrier layer is a less stable.

The ALD process is carried out at a temperature range of 50° C. to 450° C., such as 50° C. to 100° C., 50° C. to 150° C., 100° C. to 200° C., 150° C. to 250° C., 200° C. to 300° C., and 1000° C. to 400° C., and preferably at about 200° C. in a hot-walled viscous flow ALD reactor. For example, the tungsten barrier layer precursor is exposed to the substrate and the precursor reacts to bond to the substrate. A purge step may optionally be used where inert gas such as N or Ar flows continuously for 0.1 to 100 s and preferably about 1 s. Alternatively the purge step can consist of evacuating the reactor to a pressure of 0.1 to 1e-10 Torr and preferably about 1 e-3 Torr. yes

Next, the co-reactant precursor, such as TMA, is exposed to the metal, such as tungsten, bound to the substrate. The TMA reduces the tungsten fluoride terminated surface such that in various embodiments, AlWₓF_{y}C_{z} is formed where x and y are any non-zero positive number and wherein z can be zero (no carbide), or any positive number.

Generally, the barrier layer may be deposited using cycles of ALD of a(metal precursor, purge, coreactant precursor, purge). For example, a((WF6, purge—TMA, purge).

In some embodiments, the precursors, such as TMA and WF₆, are maintained at room temperature and ultrahigh purity N₂ is used as a carrier gas with a mass flow rate of 300 sccm. The base pressure of the ALD reaction chamber is maintained at ˜1.0 Torr. TMA and WF₆ were alternatively pulsed into the 300 sccm of N₂ carrier flow with the following time sequence: 1 s WF₆ dose—5 s purge—1 s TMA dose—5 s purge.

With regard to method for depositing the metal layer, at least one metal precursor is included. This second metal precursor is one capable of both deposing a pure metal and capable of bonding with the barrier layer. In one embodiment, the second metal precursor is selected from the group consisting of: WF6, WCl6, WBr5, MoF6, MoF4, MoCl6, TaF5, TaCl5, NbF5, NbCl5, NbBr5, TiF4, TiCl4, TiBr4, TiI4, ZrCl4, HfCl4. The method for depositing the metal layer may further utilize a reducing precursor. The reducing precursor is utilized in a cycle with the metal precursor and the co-reactant precursor to form the metal composite layer. The reducing precursor is selected from materials that are capable of reducing the bound metal precursor. For certain embodiments, including but not limited to Si₂H₆, SiH₄, BH₃, B₂H₆, H2 ethanol, methanol, trimethyl boron, diethyl zinc, trimethyl aluminum, trimethyl gallium, trimethyl phosphate, precursor with tert-butaoxide compound (Al-tert butaoxide) or combinations thereof. In some embodiments, a purge step is utilized after one or more of the metal precursor exposure and the reducing precursor exposure. Generally, the metal layer is deposited using an ALD cycle of b(metal precursor, purge, metal reducing precursor, purge). Thus, a tungsten layer may be deposited using an ALD cycle comprising b(WF6.Si₂H₆,) where b is the number of times the cycle is repeated and where a purge occurs after each precursor dosage.

In one embodiment, the barrier layer and the metal layer are amenable to the use of the same ALD reactor. In such embodiments, the deposition of both layers may be done as a supercycle of For example, N(( )(b(WF6.Si₂H₆,))) where a and b are the number of cycles of the respective deposition of the barrier and metal layers and N is the total number of times that supercycle is repeated (purge steps are also included). The ratio of a and b can be, for example, 1:3, 1:5, 1:10, 1:25 and ratios therebetween. The total thickness may be the same for different compositions by varying the a:b ratio providing a different relative thickness metal between each barrier layer.

Some embodiments utilize ALD for deposition of very thin continuous barrier and pure W layer on 3D multi-stack structures e.g. high aspect ratio vias, trenches, etc. The observed properties of very thin AlWₓF_{y}C_{z} barrier layer and results shows very stable performance in terms of electrical, mechanical, and chemical stability and reliability. The very thin ALD grown AlWₓF_{y}C_{z} coating is used a barrier layer and then followed with the W thin film growth by ALD. The W layer bonds with the AlWₓF_{y}C_{z} barrier layer superior to most substrates of interest.

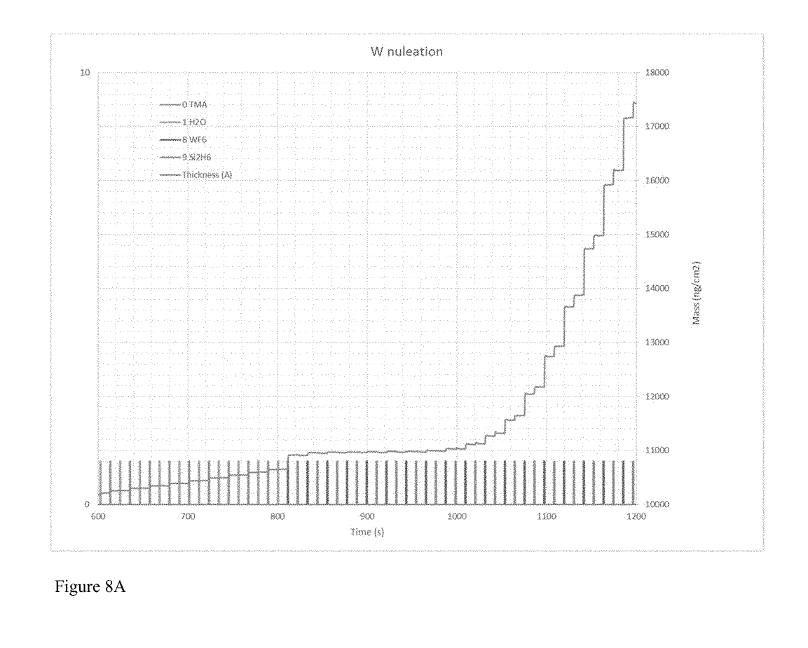

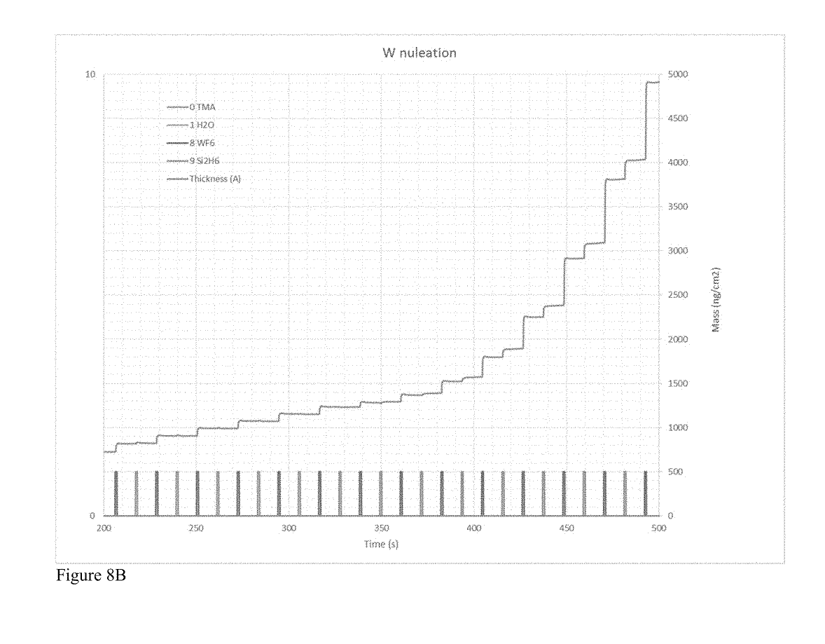

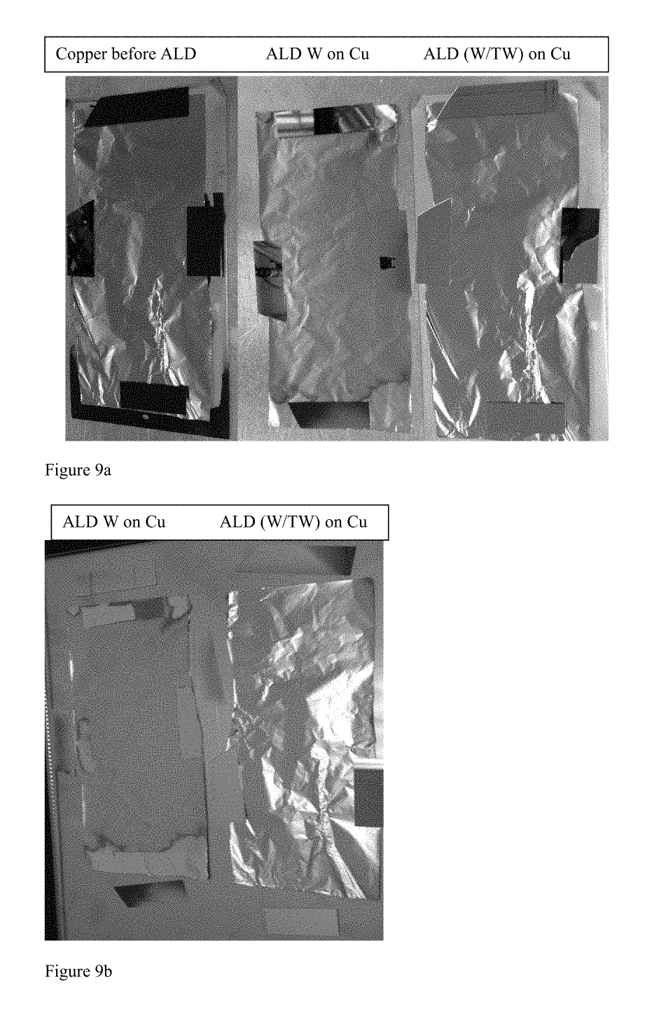

The conductivity of the overall W layer is not compromised by the use of the barrier layer. In some embodiments, the overall article of manufacture comprising the W layer and barrier layer demonstrates a higher conductivity. It is believed this is due to very little nucleation delay time on W on TW barrier. For example, see FIG. 8A for W nucleation on a on Al2O3 barrier layer and FIG. 8B illustrating W nucleation on a TW barrier layer. In comparison to tungsten grown on a metal oxide layer, W growth on the barrier layer started immediately and resulted in a thicker W layer for same deposition time or ALD cycles and better crystallinity, material density. Furthermore experiments have shown improved resistance to delamination of the pure thick W layer when the TW metal barrier layer is deposited directly on Si substrate.

In some embodiments the method includes alternating deposition of the W layer with additional barrier layers. Thus, the W layer includes intervening barrier layers or additional (second, third, etc) barrier layers.

### Experimental

In order to analyze the certain methods and articles of manufacture consistent with the above description, a series of experiments were performed.

In one set of experiments, a thin barrier layer TW was deposited using TMA-WF6 at 200 C by ALD method as known in the art. A pure W layer was deposited using Si2H6-WF6 at 200 C by a typical ALD method as known in the art. The silicon wafer used was 300 mm. \

For the experiments, the total number of WF6 doses was fixed at 125. For example, ALD sequencing schemes included:

1) 125×(Si2H6-WF6) ALD cycles for pure W ALD on bare Si and 100 nm ALO//Si

2) 25×(TMA-WF6) barrier+100×(Si2H6-WF6) pure W ALD on bare Si

3) 25×(1×(TMA-WF6)+4(Si2H6-WF6)) ALD cycles on bare Si

4) 62×(1×(TMA-WF6)+1×(Si2H6-WF6)) ALD cycles on bare Si

Any non-uniformity (NU) in the thickness/resistance can be improve with showerhead type ALD/CVD reaction chambers.

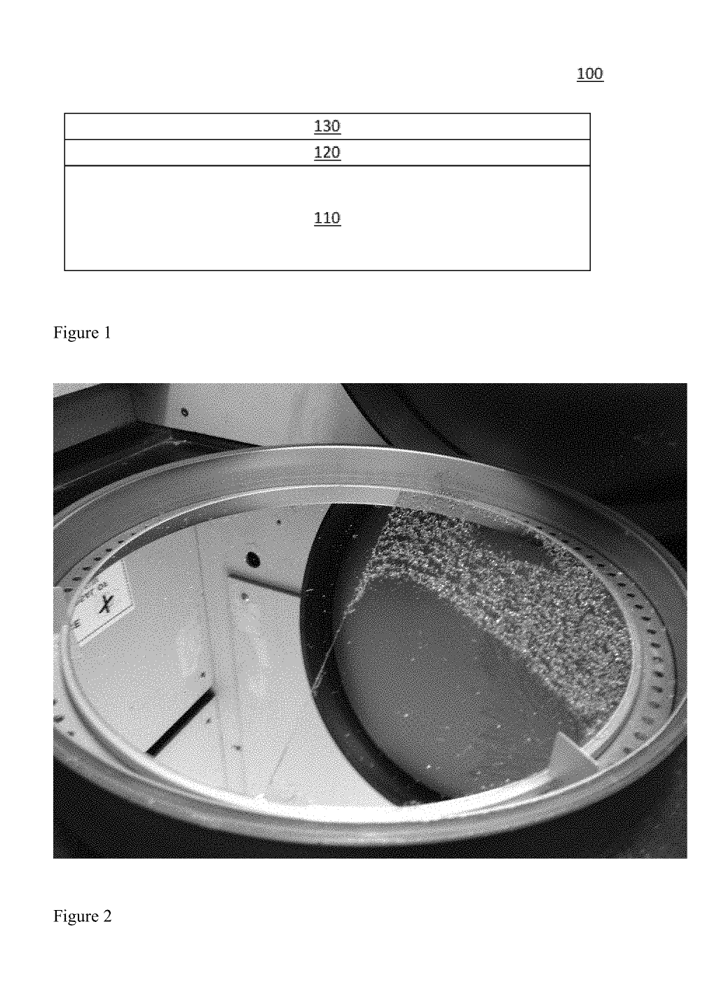

FIG. 2 illustrates a wafer with W-Deposition by ALD using 125 cycles of (Si2H6-WF6) at 200 C on bare Si (right side of wafer) and 100 nm ALO barrier layer coated on Si (left side of wafer). As can be seen in the photo, the left side having the ALO barrier layer shows little to no delamination. The tungsten grown on bare Si, right side of wafer, shows severe delamination of the tungsten layer.

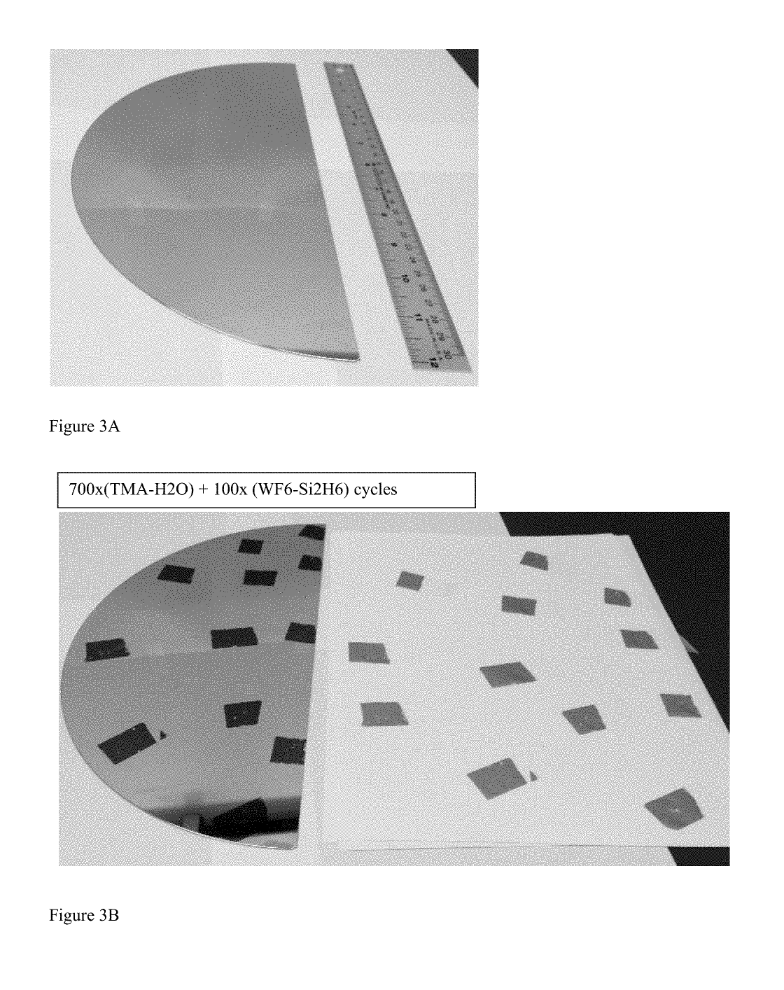

FIG. 3 A is a photograph of an adhesion test on a coated substrate comprising an aluminum oxide barrier layer and a tungsten layer. An W-Adhesion test was performed on a sample with a tungsten layer on a 100 nm ALO barrier layer coated on Si. Although W layer grew nicely on Al2O3 passivated substrate the W adhesion with diamond scribe and scotch tape peel test failed. The dark layer is 100 nm AL2O3 can be seen easily after peel test. This type of tungsten will not pass a standard CMP test. FIG. 3B shows the coated substrate after a scotch tape peel test. FIG. 3C shows the results of the test.

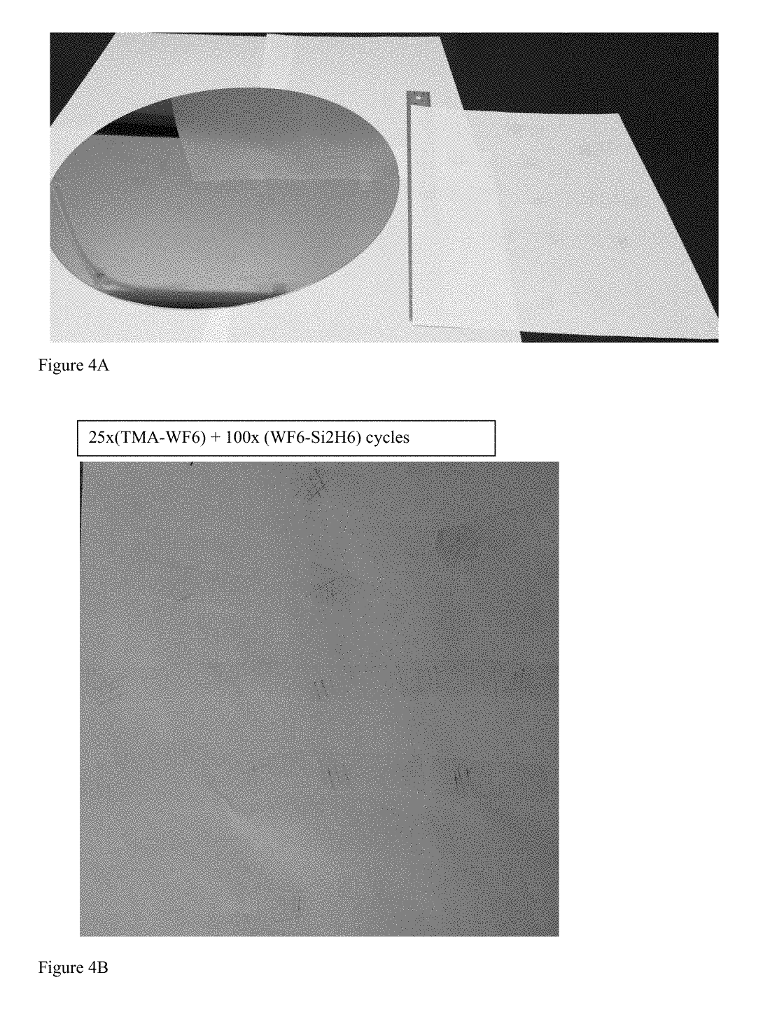

FIG. 4A is a photograph of an adhesion test on a coated substrate comprising a thin TW barrier layer and a tungsten layer. For this Adhesion test of a W layer deposited with thin TW barrier layer directly on Si wafer. The test used 25 cycles of TW (TMA-WF6) ALD followed by 100 cycles of pure W (WF6-Si2H6) ALD at 200 C. The results of the scotch tape test clearly indicate that the W layer adhesion was very robust. The line marks on paper on the bottom photo is from dust of W and Si substrate that sticks to scotch tape occurs during diamond scribing.

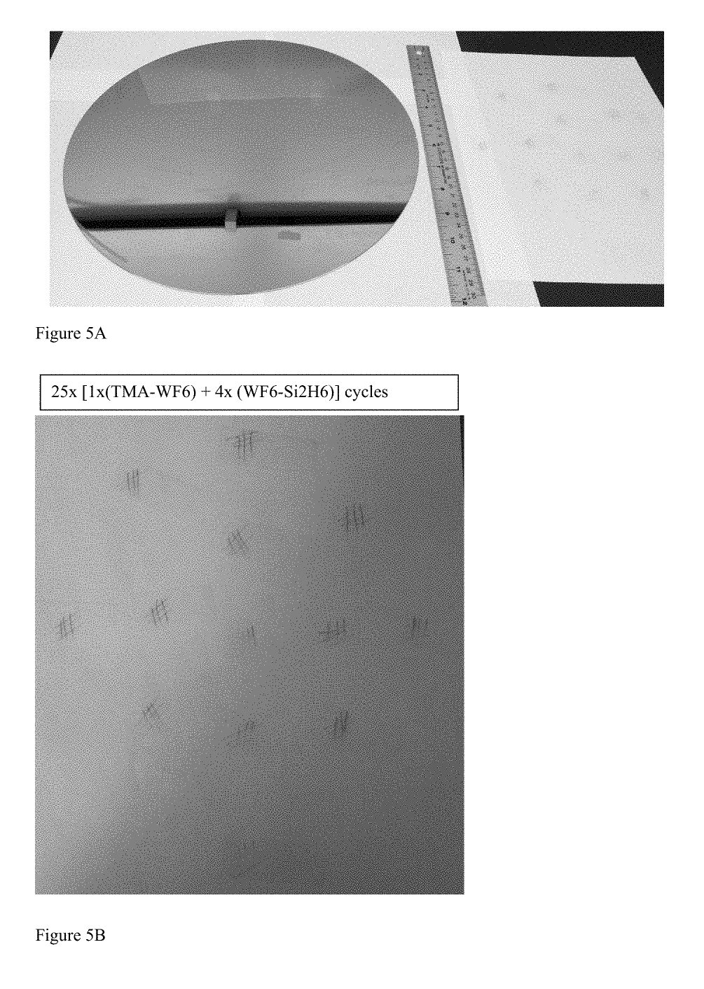

FIG. 5A is a photograph of an adhesion test on a coated substrate comprising a W layer deposited with intermediate addition of thin TW barrier layer in pure tungsten ALD process directly on Si wafer. The tested sample comprised 25×(1×TW (TMA-WF6)+W 4×(WF6-Si2H6)) ALD deposited at 200 C. Photos shown below clearly indicates that W layer adhesion was very robust. The line marks on paper on the bottom photo is from dust of W and Si substrate that sticks to scotch tape occurs during diamond scribing.

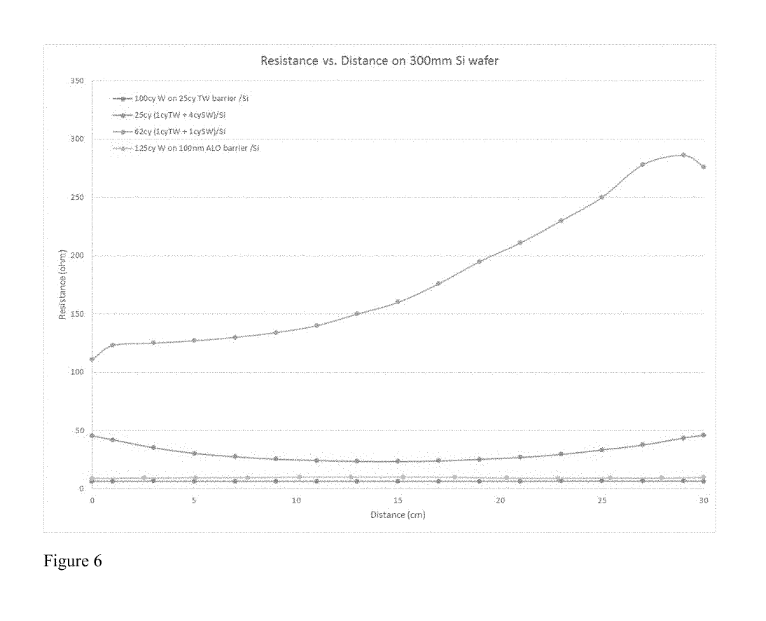

Testing was also performed to measure improvement of W conductivity. A sample comprising 25×(TMA-WF6) barrier layer+pure W 100×(Si2H6-WF6) pure W with 125×(Si2H6-WF6) was tested. It is believed that a very small nucleation delay resulted in thicker W layer or better crystallinity (larger grain, density). FIG. 6 is a graph of the resistance data as a function of distance on a 300 mm silicon wafer.

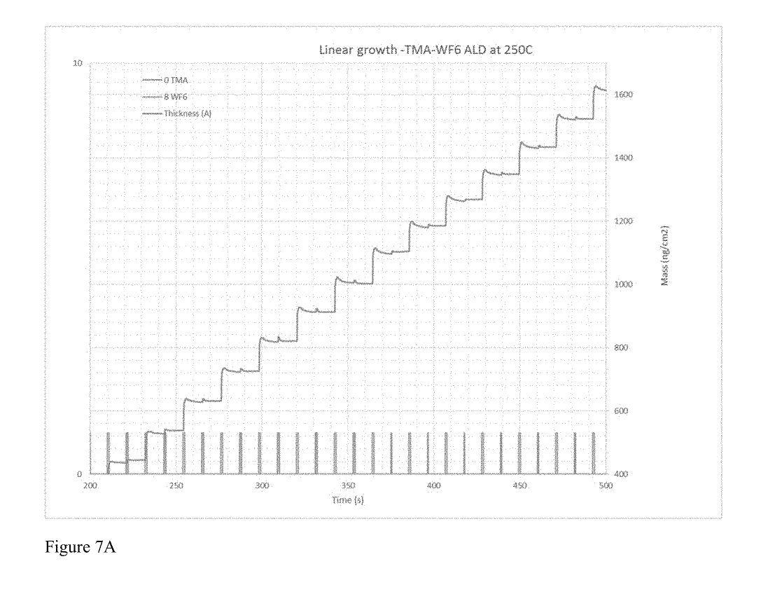

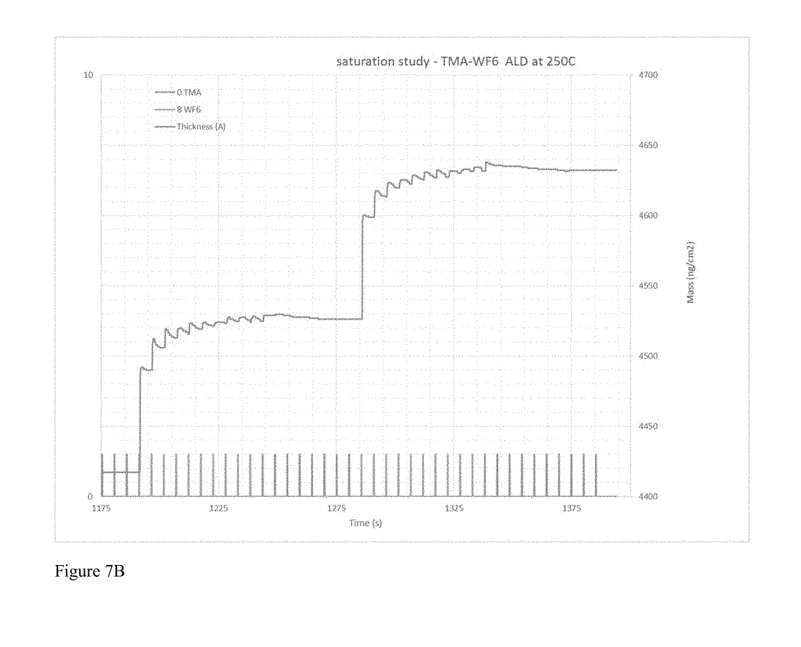

FIGS. 7A and 7B illustrate review of a formation of a TW layer by ALD. FIG. 7A illustrates step-wise linear growth. FIG. 7B illustrates saturation for the ALD of FIG. 7A.

As used herein, the singular forms “a”, “an” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A method of preparing a tungsten layer on a substrate comprising:
depositing a barrier layer on the substrate by:
performing atomic layer deposition of WF₆ at a first deposition temperature between 100° C. and 400° C.;
purging the WF₆; and
performing atomic layer deposition of TMA at a second deposition temperature between 100° C. and 400° C.;
purging the TMA;
depositing a tungsten layer on the barrier layer by:
performing atomic layer deposition of WF₆ at a third deposition temperature between 100° C. and 400° C.;
purging the WF₆;
performing atomic layer deposition of a reducing precursor at a fourth deposition temperature between 100° C. and 400° C.; and
purging the reducing precursor.

2. The method of claim 1, wherein the reducing agent is selected from Si₂H₆, SiH₄, BH₃, B₂H₆, H2 ethanol, methanol, trimethyl boron, diethyl zinc, trimethyl aluminum, trimethyl gallium, trimethyl phosphate, precursor with tert-butaoxide compound (Al-tert butaoxide) or combinations thereof.

3. The method of claim 1 wherein the first and second deposition temperatures are the same.

4. The method of claim 1 wherein the third and fourth deposition temperatures are the same.

5. The method of claim 1, wherein the substrate comprises a material selected from oxides, nitrides, semiconductors, metals and polymers.

6. The method of claim 1, wherein the barrier layer comprises AlWₓYF_{y}C_{z}, where x and y are greater than 0.

7. The method of claim 5, wherein z is greater than 0.

8. The method of claim 5, wherein the barrier layer has a thickness of less than about 1 nm.

9. The method of claim 5, further comprising an second barrier layer deposited by atomic layer deposition on the tungsten layer by:
performing atomic layer deposition cycles with WF₆;
purging the WF₆; and
performing atomic layer deposition cycles of TMA;
purging the TMA;
with a second tungsten layer deposited by atomic layer deposition on the second barrier layer.

10. A method of preparing a tungsten layer on a substrate comprising:
depositing a barrier layer comprising M₁C_{z}/M₂Xₘ on the substrate by performing a cycles of ALD comprising:
deposition of a metal precursor M₁Xₙ(g) at a first deposition temperature between 100° C. and 400° C.;
purging the metal precursor; and
deposition of a coreactant precursor M₂Rₘ(g) at a second deposition temperature between 100° C. and 400° C.; and
purging the coreactant precursor;
wherein M₁ is a first metal, wherein M₂ is a second metal X is a halogen, R is an alkyl ligand
depositing a tungsten layer on the barrier layer by performing b cycles of ALD comprising:
deposition of a second metal precursor at a third deposition temperature between 100° C. and 400° C.; and
deposition of a reducing precursor at a fourth deposition temperature between 100° C. and 400° C.

11. The method of claim 10, wherein the coreactant precursor is selected from the group consisting of AlMe3, ZnMe2, ZnEt2, CdMe2, CdEt2, AlEt3, GaMe3, GaEt3, InMe3, InEt3, SnMe4, Mg(Cp)2, Ca(Cp)2, Sr(Cp)2, Ba(Cp)2, Sc(Cp)3, Y(Cp)3, La(Cp)3, where Cp is cyclopentadiene or a substituted cyclopentadienes, Co(amd)2, Ni(amd)2, Fe(amd)2, Mg(amd)2, Ca(amd)2, Sr(amd)2, Ba(amd)2, where amd is an amidinate ligands

12. The method of claim 10, wherein the metal precursor is selected from the group consisting of: WF6, WCl6, WBr5, MoF6, MoF4, MoCl6, TaF5, TaCl5, NbF5, NbCl5, NbBr5, TiF4, TiCl4, TiBr4, TiI4, ZrCl4, HfCl4.

13. The method of claim 11, wherein the first metal precursor and the second metal precursor are the same.

14. The method of claim 11, wherein the ratio of a cycles to b cycles is

15. The method of claim 10, wherein the barrier layer has a thickness of between 10 nm and 1 atomic thickness.

16. The method of claim 10, wherein the second metal precursor is selected from the group consisting of: WF6, WCl6, WBr5, MoF6, MoF4, MoCl6, TaF5, TaCl5, NbF5, NbCl5, NbBr5, TiF4, TiCl4, TiBr4, TiI4, ZrCl4, HfCl4.

17. The method of claim 10, wherein the reducing agent is selected from Si₂H₆, SiH₄, BH₃, B₂H₆, H2 ethanol, methanol, trimethyl boron, diethyl zinc, trimethyl aluminum, trimethyl gallium, trimethyl phosphate, precursor with tert-butaoxide compound (Al-tert butaoxide) or combinations thereof.

18. An article of manufacture comprising:
a substrate;
a barrier layer comprising AlWₓF_{y}C_{z}, where x and y are any non-zero positive number and wherein z is be zero or any positive number; and
a tungsten layer deposited on the barrier layer.

19. The article of manufacture of claim 18, further comprising an intervening barrier layer disposed within the tungsten layer and comprising AlWₓF_{y}C_{z}.

20. The article of manufacture of claim 15, wherein the barrier layer has a thickness of less than 1 nm.
